(19) United States
(12) Patent Application Publication
(10) Pub. No.: US 2009/0189624 A1
(43) Pub. Date: Jul. 30, 2009

(54) Interposer and a probe card assembly for electrical die sorting and methods of operating and manufacturing the same

(75) Inventors: Se-Jang Oh, Seongnam-si (KR); Hal-young Lee, Seongnam-si (KR); Young-soo An, Yongin-si (KR); Sang-hoon Lee, Hwaseong-si (KR); Sung-ho Joo, Seoul (KR); Dong-yeop Kim, Muan-gun (KR)

Correspondence Address: HARNESS, DICKEY & PIERCE, P.L.C., P.O. BOX 8910, RESTON, VA, 20195, US

(73) Assignees: SAMSUNG ELECTRONICS CO., LTD.; AJOU UNIVERSITY INDUSTRY-ACADEMY COOPERATION FOUND

(21) Appl. No.: 12/232,963

(22) Filed: Sep. 26, 2008

(30) Foreign Application Priority Data
Jan. 28, 2008 (KR) 10-2008-0008730

(51) Int. Cl. G01R 31/02; H01R 12/00

(52) U.S. Cl. 324/754; 439/66

(57) ABSTRACT

An interposer and a probe card assembly for electrical die sorting is provided. The assembly may include probes electrically contacting pads of dies on a substrate, a first wiring unit including a first wire on and electrically contacting the probes, an interposer unit including interposers on the first wiring unit and electrically contacting the first wire, and a second wiring unit including a second wire on the interposer unit and electrically contacting the interposers. At least one interposer includes a conductive member, a first connection member adjacent to a first end of the conductive member so as to electrically connect the conductive member to the first wire, a second connection member adjacent to a second end of the conductive member so as to electrically connect the conductive member to the second wire, and at least one protrusion member on an external surface of the conductive member between the first and second connection members.

### PRIORITY STATEMENT

This application claims the benefit of priority under 35 U.S.C. §119 from Korean Patent Application No. 10-2008-0008730, filed on Jan. 28, 2008, in the Korean Intellectual Property Office, the disclosure of which is incorporated herein in its entirety by reference.

### BACKGROUND

1. Field

Example embodiments relate to an interposer and a probe card assembly for an electrical die sorting (EDS) process and methods of operating and manufacturing the same. Other example embodiments relate to an interposer and a probe card assembly for an EDS process, wherein high frequency signals for a die test may be transmitted without signal distortion.

Other example embodiments relate to a probe card used in an electrical die sorting (EDS) process for detecting malfunctions in chips formed on a wafer and a probe test device including the probe card.

2. Description of the Related Art

A process for manufacturing semiconductor devices may be categorized into a fabrication process, an EDS process and/or a packaging process. In the fabrication process, integrated circuits (ICs) may be formed by providing desired patterns on a wafer. In the packaging process, the wafer, on which the ICs are formed, may be cut into unit chips for packaging. In the EDS process, after the fabricating process is performed, electrical characteristics of the unit chips formed on the wafer may be tested before the wafer is cut into the unit chips during the packaging process. In the EDS process, a test on the electrical characteristics of each unit chip may be performed on the wafers. By performing an EDS process, malfunctioning chips may be detected prior to use, and accordingly repaired. As such, the costs associated with performing a package test process during the packaging process may decrease.

In an EDS process, a wafer having dies formed thereon may be tested using a probe card assembly. The probe card assembly includes a first wiring substrate having probes arranged to correspond to, and electrically contact, the dies. A second wiring substrate, which is connected to an external analysis apparatus, may be provided. The second wiring substrate may have a larger size than the first wiring substrate. An interposer may be provided that electrically connects the first and second wiring substrates to each other.

FIG. 1 is a perspective view of a plurality of interposers 1 according to the conventional art.

Referring to FIG. 1, each of the interposers 1 includes a conductive unit 2 and connection units 4, which are formed on ends of the conductive unit 2. The connection units 4 may have elasticity. As such, electrical connection between a first wiring substrate (not shown) and a second wiring substrate (not shown) may be more firmly ensured when probes (not shown) contact dies formed on a wafer. The interposers 1 may be surrounded by a housing 5.

As a clock frequency of a semiconductor device increases, electrical characteristics of a probe card assembly become more significant. In order to increase the electrical characteristics of the probe card assembly in a relatively high frequency region, impedance-matching between elements in the probe card assembly may be desirable. If the impedance-matching between the elements in the probe card assembly is poor, unwanted signal reflection increases. As such, a range of frequencies to be used by the probe card assembly may be restricted. For example, a K3 probe card for testing double-data-rate two (DDR2) memory has only several hundred megahertz (MHz) of −3 dB frequencies. As such, a K3 probe card may be limited, or restricted in its ability, to test a semiconductor device having a clock frequency of several gigahertz (GHz) or more.

The interposers 1 may be used in a K3 probe card. The interposers 1 may have substantially high inductive factors. The high inductive factors may distort test signals transmitted to probes and/or electrical characteristic signals transmitted from the probes. As such, the ability of a conventional probe card assembly to more accurately detect a malfunctioning die, may be restricted.

### SUMMARY

Example embodiments relate to an interposer and a probe card assembly for an electrical die sorting (EDS) process and methods of operating and manufacturing the same. Other example embodiments relate to an interposer and a probe card assembly for an EDS process, wherein high frequency signals for a die test may be transmitted without signal distortion.

Other example embodiments relate to a probe card used in an electrical die sorting (EDS) process for detecting malfunctions in chips formed on a wafer and a probe test device including the probe card.

Example embodiments provide a probe card assembly for more accurately performing an electrical die sorting (EDS) process by preventing (or reducing) distortion of high frequency signals for a die test.

According to example embodiments, there is provided a probe card assembly including a plurality of probes that electrically contact pads of dies formed on a substrate to test the dies, a first wiring unit including a first wire disposed on and electrically contacting the probes, an interposer unit including a plurality of interposers disposed on the first wiring unit and electrically contacting the first wire, and a second wiring unit including a second wire disposed on the interposer unit and electrically contacting the interposers.

At least one of the interposers may include a conductive member, a first connection member formed adjacent to a first end of the conductive member so as to electrically connect the conductive member to the first wire, a second connection member which is formed adjacent to a second end of the conductive member so as to electrically connect the conductive member to the second wire, and at least one protrusion member formed on an external surface of the conductive member between the first and second connection members.

Each of the interposers may include at least one protrusion member. The protrusion member may be formed adjacent to a first end a desired distance from a center of the conductive member. The protrusion member may be formed adjacent to a second end a desired distance from a center of the conductive member. The protrusion member may be formed adjacent to the first and second ends. The number of the protrusion members formed adjacent to the first end of the conductive member may be the same as the number of the protrusion members formed adjacent to the second end the conductive member.

The interposers may include signal interposers for transmitting electrical signals, and ground interposers connected to a ground. The at least one signal interposer and the at least one ground interposer may be included in an interposer group. The at least one signal interposer and the at least one ground interposer included in the same interposer group may be electrically connected to each other.

The at least one signal interposer or the at least one ground interposer included in the same interposer group may include at least one protrusion member. The protrusion member may be formed adjacent to the first end of the conductive member. The protrusion member may be formed adjacent to the second end of the conductive member. The protrusion member may be formed adjacent to the first and second ends of the conductive member. The number of the protrusion members formed adjacent to the first end of the conductive member may be the same as (or equal to) the number of the protrusion members formed adjacent to the second end of the conductive member.

The outer shape of the protrusion members may be in a circular shape, an oval shape, a polygonal shape or the like. The protrusion members may have the same size. The protrusion members may have a larger external diameter than that of at least one of the first and second connection members.

The protrusion members may be conductors. The protrusion members may include carbon (C) or metal.

The conductive member may have a circular cylinder shape, a polygonal cylinder shape, a hollow shape or the like. The conductive member may include carbon (C), metal or the like.

The interposers may be surrounded by a housing.

### BRIEF DESCRIPTION OF THE DRAWINGS

Example embodiments will be more clearly understood from the following detailed description taken in conjunction with the accompanying drawings. FIGS. 1-5C represent non-limiting, example embodiments as described herein.

FIG. 1 is a perspective view of conventional interposers;

FIG. 2 is a cross-sectional view of a probe card assembly according to example embodiments;

FIG. 3A is a perspective view of a plurality of interposers in the interposer unit illustrated in FIG. 2;

FIG. 3B is a front view of a pair of interposers in the interposer unit illustrated in FIG. 2;

FIG. 3C is a plan view of a pair of interposers in the interposer unit illustrated in FIG. 2;

FIG. 4A is a diagram showing a simulation result of a distribution of electric fields applied to a pair of conventional interposers while electric signals are being transmitted;

FIG. 4B is a diagram showing a simulation result of a distribution of electric fields applied to a pair of interposers according to example embodiments while electric signals are being transmitted;

FIG. 5A is a graph showing the change in signal transmittance over various frequencies for interposers according to example embodiments and conventional interposers;

FIG. 5B is a graph showing the change in impedance over time for interposers according to example embodiments and conventional interposers; and

FIG. 5C is a graph showing eye patterns of interposers according to example embodiments and conventional interposers.

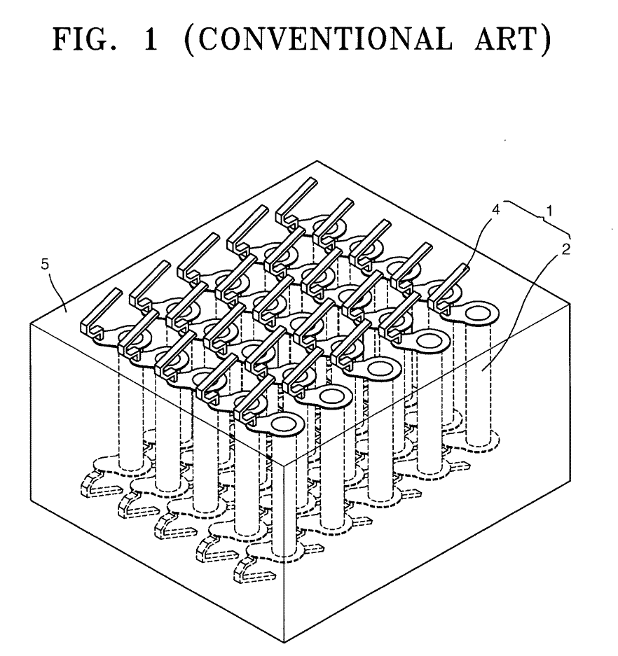

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention, however, may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe example embodiments, various aspects will be described in detail with reference to the attached drawings. However, the present invention is not limited to example embodiments described.

Example embodiments relate to an interposer and a probe card assembly for an electrical die sorting (EDS) process and methods of operating and manufacturing the same. Other example embodiments relate to an interposer and a probe card assembly for an EDS process, wherein high frequency signals for a die test may be transmitted without signal distortion.

Other example embodiments relate to a probe card used in an electrical die sorting (EDS) process for detecting malfunctions in chips formed on a wafer and a probe test device including the probe card.

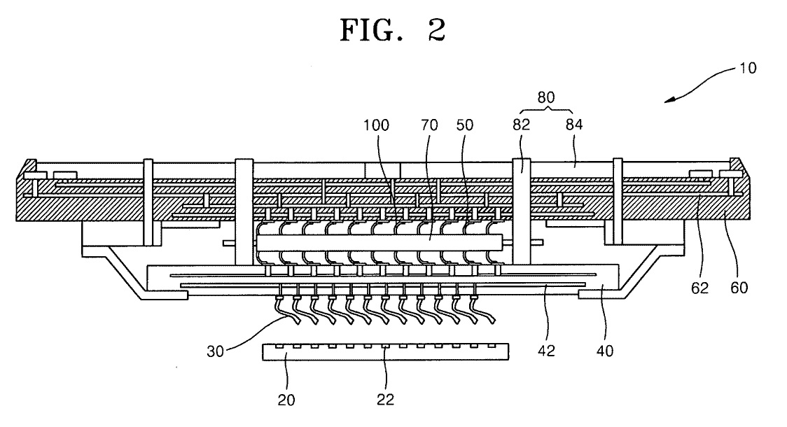

FIG. 2 is a cross-sectional view of a probe card assembly 10 according to example embodiments.

Referring to FIG. 2, in an electrical die sorting (EDS) process, a plurality of pads (not shown) formed on a plurality of dies 22 may electrically contact a plurality of probes 30 in order to perform a test. The plurality of dies 22 may be on a substrate 20. The probe card assembly 10 may include the plurality of probes 30, a first wiring unit 40, an interposer unit 50 and a second wiring unit 60.

The first wiring unit 40 includes a first wire 42 disposed on and electrically contacting the probes 30. The first wiring unit 40 may be a printed circuit board (PCB) (e.g., a multi-layer ceramic (MLC) substrate or a flame retardant 4 (FR4) substrate). However, example embodiments are not limited thereto.

The interposer unit 50 includes a plurality of interposers 100 disposed on the first wiring unit 40 and electrically contacting the first wire 42. The interposer unit 50 may include a housing 70 surrounding the interposers 100. For example, the housing may be formed of a nonconductor (e.g., plastic or ceramic).

The second wiring unit 60 includes a second wire 62 disposed on the interposer unit 50 and electrically contacting the interposers 100. The second wiring unit 60 may be a PCB (e.g., an MLC substrate or an FR4 substrate). However, example embodiments are not limited thereto.

In the probe card assembly 10, the probes 30, the first wiring unit 40, the interposer unit 50 and the second wiring unit 60 may be connected to each other by a support unit 80. The support unit 80 may include a plurality of connection members 82, which connect the first wiring unit 40, the interposer unit 50 and the second wiring unit 60. The support unit 80 may include a supporting member 84, which is adhered to (or formed on) a side of the second wiring unit 60 facing the first wiring unit 40. The support unit 80 elastically supports the first wiring unit 40, the interposer unit 50 and the second wiring unit 60. The shape, position and number of the support unit 80 may vary.

A method of operating the probe card assembly 10 will now be described. The probes 30 of the probe card assembly 10 contact the pads (not shown) of the dies 22 formed on the substrate 10 using an external transfer apparatus (not shown). An external detecting apparatus (not shown) may apply test signals to the pads through the second wiring unit 60, the interposer unit 50, the first wiring unit 40 and the probes 30. In correspondence with the test signals, electrical characteristic signals may be generated from the dies 22 and transmitted to the external detecting apparatus through the probes 30, the first wiring unit 40, the interposer unit 50 and the second wiring unit 60 in order to determine dies 22 that are malfunctioning and dies 22 that are functioning properly.

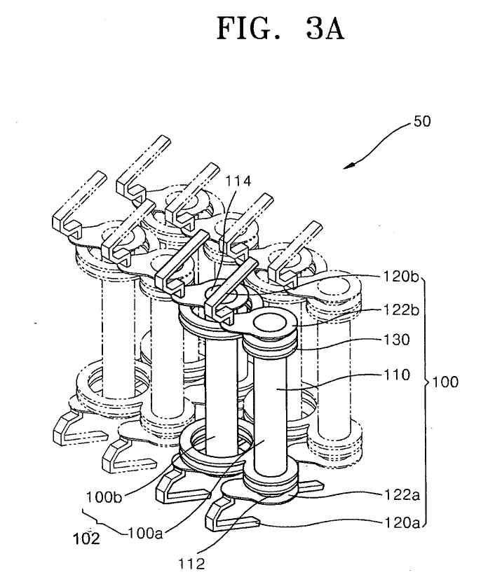

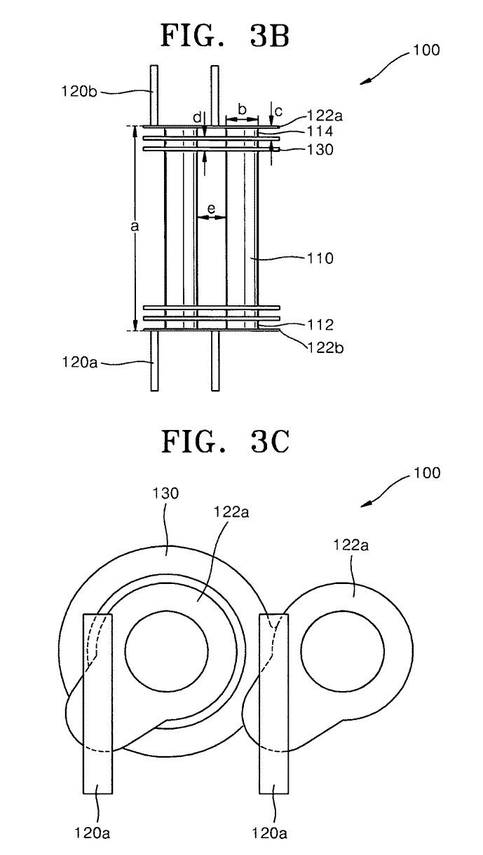

FIG. 3A is a perspective view of the interposers included in the interposer unit illustrated in FIG. 2.

Referring to FIG. 3A, each of the interposers 100 includes a conductive member 110, first and second connection members 120a and 120b and at least one protrusion member 130. The first connection member 120a may be connected to a first intermediate member 122a formed adjacent to a first end 112 of the conductive member 110 so as to electrically connect the conductive member 110 to the first wire 42 of the first wiring unit 40 illustrated in FIG. 2. The second connection member 120b may be connected to a second intermediate member 122b formed adjacent to a second end 114 of the conductive member 110 so as to electrically connect the conductive member 110 to the second wire 62 of the second wiring unit 60 illustrated in FIG. 2.

In order to ensure an electrical connection between the conductive member 110 and the first and second wiring units 40 and 60, the first and second connection members 120a and 120b may be formed of a material having elasticity (e.g., metal such as copper (Cu), aluminum (Al), iron (Fe), silver (Ag), gold (Au), platinum (Pt) or the like). The first and second connection members 120a and 120b may have an L-shape as shown in FIG. 3A or a spring shape. However, example embodiments are not limited thereto.

The conductive member 110 may include a conductive material (e.g., carbon (C) or metal). For example, the metal may be Cu, Al, Fe, Ag, Au, Pt or the like). The conductive member 110 may have a circular cylinder shape, a polygonal cylinder shape or a pipe shape. The conductive member 110 may be covered by the housing 70 illustrated in FIG. 2. The conductive member 110 may be independently formed, or may be formed simultaneously with the housing 70.

A method of forming the conductive member 110 according to example embodiments will now be described. A desired number of first protrusion holes having a desired diameter may be formed in the housing 70 formed of a nonconductor. The first protrusion holes may be filled with a conductive material (e.g., carbon (C)) or metal (e.g., Cu, Al, Fe, Ag, Au, Pt or the like. Second protrusion holes, having a smaller diameter than the first protrusion holes, may be formed such that the conductive material continuously and uniformly remains on internal surfaces of the first protrusion holes. As such, each pipe-shaped structure, which is generated by formation of the second protrusion holes, functions as the conductive member 110 formed of the conductive material. However, example embodiments are not limited thereto.

The protrusion members 130 may be formed on an external surface of the conductive member 110 between the first and second connection members 120a and 120b. The protrusion members 150 electrically contact the conductive member 110. Each of the interposers 100 may include at least one protrusion member 130. The protrusion member 130 may be formed of a conductive material (e.g., carbon (C) or metal). The metal may be at least one selected from the group consisting of Cu, Al, Fe, Ag, Au, Pt and combinations thereof.

The outer shape of the protrusion members 130 may be a circular shape or an oval shape. The outer shape of the protrusion members 130 may be a polygonal shape (e.g., a square, a pentagon, a hexagon, an octagon or the like). The protrusion members 130 may have the same size. The protrusion members 130 may have a larger external diameter than at least one of the first and second connection members 120a and 120b.

The protrusion members 130 may be formed adjacent to (or near) the first end 112 of the conductive member 110, adjacent to the second end 114 of the conductive member 110, or adjacent to both the first and second ends 112 and 114 of the conductive member 110. Using the center of the conductive member 110 as a reference, the protrusion members 130 may be positioned closer to the first end 112 or the second end 114 of the conductive member 110.

The number of the protrusion members 130 formed adjacent to the first end 112 and the number of the protrusion members 130 formed adjacent to the second end 114 may be the same, or different from each other. The protrusion members 130 may be formed throughout the interposer unit 50 in a length direction of the conductive member 110. The shape, position and number of the protrusion members 130 may vary. The shape, position and/or number of the protrusion members 130 may vary in accordance with conditions necessary for preventing (or reducing) signal distortion that occur while high frequency electric signals are being transmitted (described later). Variations in the shape, position and/or number of the protrusion members 130 are included in the scope and spirit of example embodiments.

The protrusion members 130 may be independently formed, or simultaneously formed with the housing 70. The housing 70 may be formed by stacking and combining nonconductor materials, each including the conductive member 110 and the protrusion members 130. However, example embodiments are not limited thereto.

The interposers 100 may include at least signal interposers 100a for transmitting electric signals, and ground interposers 100b connected to a ground. The at least one signal interposer 100a and the at least one ground interposer 100b may form an interposer group 102. The at least one signal interposer 100a and the at least one ground interposer 100b included in the same interposer group 102 may be electrically connected to each other. The at least one signal interposer 100a or the at least one ground interposer 100b included in the same interposer group 102 may include at least one protrusion member 130. The protrusion member 130 may have one of the above-described shapes.

The protrusion members 130 may be formed adjacent to the first end 112 of the conductive member 110, adjacent to the second end 114 of the conductive member 110, or adjacent to both the first and second ends 112 and 114 of the conductive member 110. The number of the protrusion members 130 formed adjacent to the first end 112 and the number of the protrusion members 130 formed adjacent to the second end 1 14 may be equal, or different from each other.

The protrusion members 130 may be formed throughout the interposer unit 50 in a length direction of the conductive member 110. The shape, position and/or number of the protrusion members 130 may vary. The shape, position and number of the protrusion members 130 may vary in accordance with conditions necessary for preventing (or reducing) signal distortion that occur while high frequency electric signals are being transmitted.

FIG. 3B is a front view of a pair of interposers included in the interposer unit illustrated in FIG. 2.

Referring to FIG. 3B, at least two protrusion members 130 may be formed adjacent to each of first and second ends 112 and 114 of a conductive member 110, in each of the interposers 100.

A length, a, of the conductive member 110 corresponds to the length of the interposer unit 50 illustrated in FIG. 2, The length, a, of the conductive member 100 may be in a range of about 3 mm to 10 mm, or a range of about 4 mm to 5 mm. A diameter, b, of the conductive member 110 may be in a range of approximately 0.1 mm to 1.0 mm, or in a range of about 0.5 mm to 0.7 mm. A distance, c, from the first end 112, or the second end 114, of the conductive member 110 to of the nearest the protrusion members 130 may be in a range of about 0.1 mm to 1.0 mm, or in a range of approximately 0.1 mm to 0.3 mm. A distance, d, between two neighboring (or adjacent) protrusion members 130 may be in a range of about 0.1 mm to 1.0 mm, or in a range of approximately 0.1 mm to 0.3 mm. A distance, e, between the interposers 100 may be in a range of approximately 0.5 mm to 1.5 mm. However, example embodiments are not limited thereto. The measurements between elements of the interposers 100, which may prevent (or reduce) signal distortion occurring while high frequency electric signals are being transmitted, may vary.

FIG. 3C is a plan view of a pair of interposers in the interposer unit 50 illustrated in FIG. 2.

Referring to FIG. 3C, the protrusion members 130 may have an external diameter larger than the external diameter of first intermediate member 122a (as shown in the interposer on the left of FIG. 3C), and equal to, or smaller than, the external diameter of the first and second intermediate members 122a, 122b (as shown in the interposer on the right of FIG. 3C).

The protrusion units 130 may have an external diameter larger than the external diameter of the first and second intermediate members 122a, 122b (as shown in the interposer on the left of FIG. 3C), and equal to, or smaller, than the external diameter of the second intermediate member 122b (as shown in the interposer on the right of FIG. 3C).

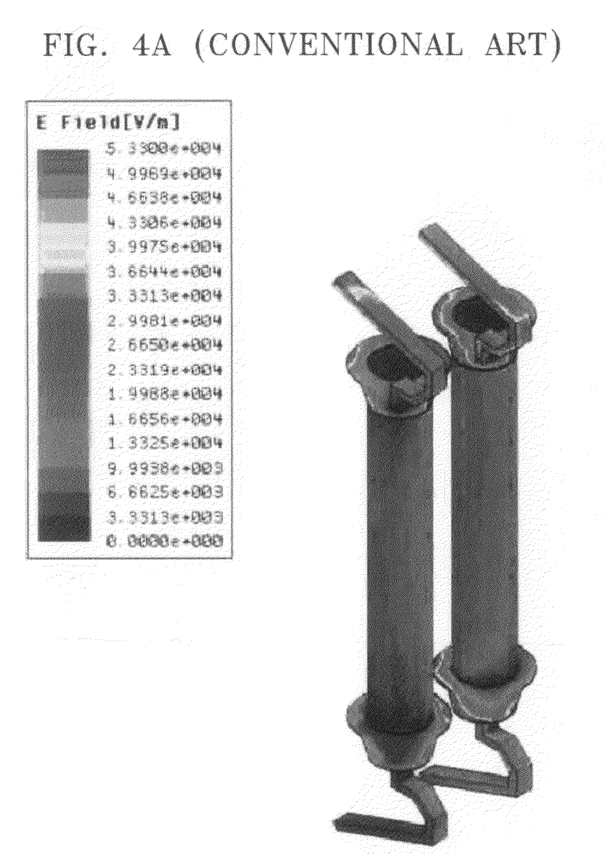

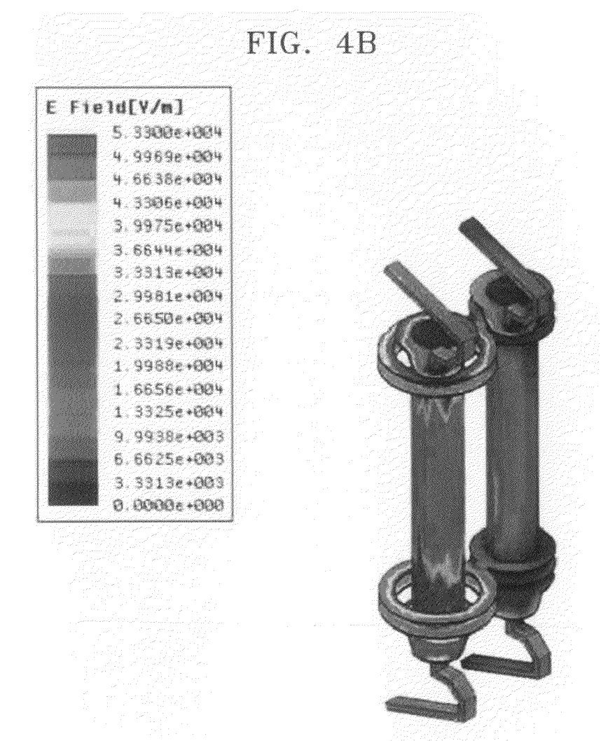

FIG. 4A is a diagram showing a simulation result of a distribution of electric fields applied to a pair of conventional interposers, while electric signals are being transmitted. FIG. 4B is a diagram showing a simulation result of a distribution of electric fields applied to a pair of interposers according to example embodiments, while electric signals are being transmitted.

Referring to FIG. 4A, high electric fields (red regions) are locally formed only at and near both ends of the conventional interposers. Low electric fields (blue regions) are formed along a length direction of the conventional interposers. As such, the flow of electric fields along the length direction of the conventional interposers is substantially weak leading to decreased signal transmittance. Because the conventional interposers have substantially high inductive factors, impedance values increase and impedance matching decreases. As such, signal distortion occurs.

Referring to FIG. 4B, red and green regions are formed in broader regions along a length direction of interposers according to example embodiments through which electric signals are being transmitted. As such, stronger electric fields are broadly formed along the length direction of the interposers according to example embodiments, thus signal transmittance increases. Because capacitance factors increase by including protrusion members, influences on inductive factors decrease. As such, the impedance values of the interposers according to example embodiments decrease and increased impedance matching may be realized.

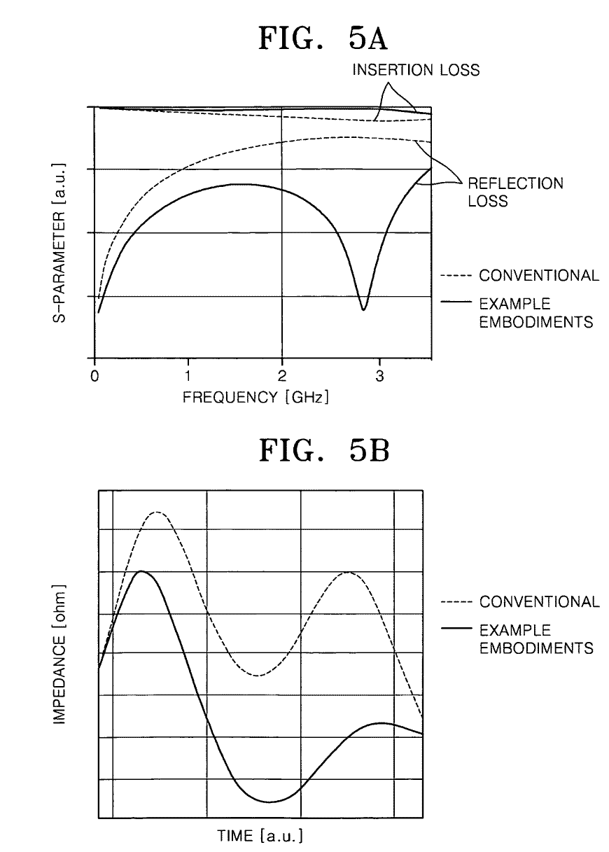

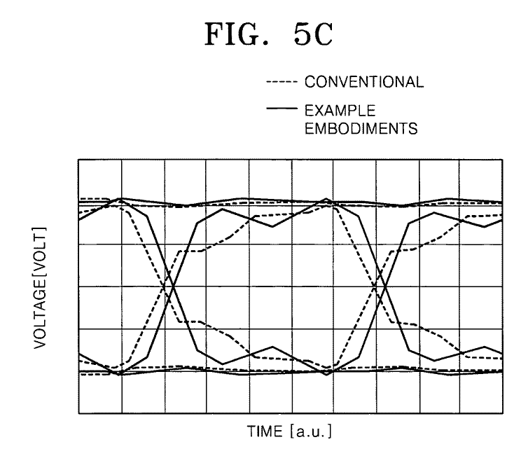

FIG. 5A is a graph showing the change in signal transmittance characteristics over various frequencies for interposers according to example embodiments and conventional interposers.

Solid lines indicate S-parameter variation curves of interposers according to example embodiments; and dotted lines indicate S-parameter variation curves of conventional interposers.

Table 1 shows insertion losses and reflection losses at select frequencies, which are obtained from the graph of FIG. 5A.

TABLE 1

| | | FREQUENCY | | |
|---|---|---|---|---|
| | | 300 MHz | 1 GHz | 3 GHz |
| CONVENTIONAL | INSERTION LOSS (DB) | −0.06 | −0.59 | −1.90 |
| INTERPOSERS | REFLECTION LOSS (DB) | −18.63 | −9.29 | −4.83 |
| INTERPOSERS OF | INSERTION LOSS (DB) | −0.04 | −0.25 | −0.28 |
| EXAMPLE EMBODIMENTS | REFLECTION LOSS (DB) | −22.43 | −13.67 | −23.23 |

Referring to FIG. 5A and Table 1, an insertion loss having a small absolute value represents, and a reflection loss having a large absolute value represents increased characteristics. In a range of 3 gigahertz (GHz), absolute values of the insertion losses of interposers according to example embodiments are relatively smaller than those of the conventional interposers. Absolute values of the reflection losses of interposers according to example embodiments are relatively larger than those of the conventional interposers. As such, the insertion losses and/or reflection losses of interposers according to example embodiments may increase. Insertion loss characteristics and reflection loss characteristics may increase substantially at a 3 GHz band, which correspond to a relatively high frequency band. Because interposers according to example embodiments include the protrusion members having capacitance factors, increased impedance matching may be realized.

FIG. 5B is a graph showing the change in impedance variations over time for interposers according to example embodiments and conventional interposers.

The graphs of FIG. 5B were obtained by performing a time domain reflection (TDR) simulation on the interposers. the solid line indicates an impedance variation curve of interposers according to example embodiments; and the dotted line indicates an impedance variation curve of conventional interposers.

Referring to FIG. 5B, in the interposers according to example embodiments, although an exact 50 Ω matching does not occur, inductive factors may decrease significantly due to capacitance factors strengthened by the protrusion members.

FIG. 5C is a graph showing eye patterns of the interposers according to example embodiments and conventional interposers. Solid lines indicate an eye pattern of interposers according to example embodiments; and dotted lines indicate an eye pattern of conventional interposers.

Referring to FIG. 5C, the eye pattern of the interposers according to example embodiments may have larger eye openings than the eye pattern of conventional interposers. An eye pattern is waveforms repetitively showing signal level movements within a desired temporal unit on a screen. An oscilloscope may measure detector output waveforms of a receiver modulator-demodulator (modem) so as to display an eye pattern. In an eye pattern, a vertically and horizontally open portion where waveforms of a signal do not cross each other is referred to as an eye opening. If a signal has increased noise, an eye opening may be relatively small. If a signal has a increased signal integrity, an eye opening may be relatively large. Clock timing and a reference voltage of a level threshold may be determined in accordance with eye openings. If eye openings are large and clean, a bit error rate (BER) may increase. As such, the interposers according to example embodiments may have an increased BER and/or signal integrity.

In a probe card assembly according to example embodiments, by using interposers including protrusion members having capacitance factors, inductive factors causing signal distortion decrease, and signal integrity may increase. In particular, an EDS test may be performed on a semiconductor device having a substantially high clock speed, by preventing (or reducing) signal distortion in a high frequency region.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. An interposer, comprising:
a conductive member;
a first connection member adjacent to a first end of the conductive member such that the conductive member is electrically connected to the conductive member;
a second connection member adjacent to a second end of the conductive member such that the conductive member is electrically connected to the conductive member; and
at least one protrusion member on an external surface of the conductive member between the first and second connection members.

2. The interposer of claim 1, further comprising a plurality of the protrusion members.

3. The interposer of claim 2, wherein the plurality of protrusion members have the same size.

4. The interposer of claim 2, wherein a first protrusion member is adjacent to a first end of the conductive member.

5. The interposer of claim 4, wherein a second protrusion member is adjacent to a second end of the conductive member.

6. The interposer of claim 2, wherein at least two of the plurality of protrusion members are adjacent to each of a first end of the conductive member, and a second end of the conductive member.

7. The interposer of claim 6, wherein an equal number of the plurality of protrusion members are adjacent to the first end of the conductive member and the second end of the conductive member.

8. The interposer of claim 1, wherein an outer shape of the at least one protrusion member is circular, oval or polygonal.

9. The interposer of claim 1, wherein the at least one protrusion member has a larger external diameter than at least one of the first and second connection members.

10. The interposer of claim 1, wherein the at least one protrusion member is a conductor.

11. The interposer of claim 1, wherein the at least one protrusion member includes carbon (C) or metal.

12. The interposer of claim 1, wherein the conductive member has a circular cylinder shape, a polygonal cylinder shape or a hollow shape.

13. The interposer of claim 1, wherein the conductive member includes carbon (C) or metal.

14. A probe card assembly, comprising:
a plurality of probes electrically contacting pads of a plurality of dies to be tested, the plurality of dies being on a substrate;
a first wiring unit including a first wire on and electrically contacting the plurality of probes;
an interposer unit including a plurality of the interposers according to claim 1, the plurality of interposers being on the first wiring unit and electrically contacting the first wire; and
a second wiring unit including a second wire on the interposer unit and electrically contacting the plurality of interposers.

15. The probe card assembly of claim 14, wherein the plurality of interposers are surrounded by a housing.

16. The probe card assembly of claim 14, wherein the plurality of interposers includes at least one signal interposer that transmits electric signals, and at least one ground interposer connected to a ground, the at least one signal interposer and the at least one ground interposer forming an interposer group and being electrically connected to each other.

17. The probe card assembly of claim 16, wherein the at least one signal interposer and the at least one ground interposer each include a plurality of the protrusion members.

18. The probe card assembly of claim 17, wherein a first protrusion member is adjacent to a first end of the conductive member, in each of the at least one signal interposer and the at least one ground interposer.

19. The probe card assembly of claim 18, wherein a second protrusion member is adjacent to a second end of the conductive member, in each of the at least one signal interposer and the at least one ground interposer.

20. The probe card assembly of claim 17, wherein at least two of the plurality of protrusion members are adjacent to each of a first end of the conductive member and a second end of the conductive member, in each of the at least one signal interposer and the at least one ground interposer.

21. The probe card assembly of claim 20, wherein an equal number of the plurality of protrusion members are adjacent to the first end of the conductive member and the second end of the conductive member, in each of the at least one signal interposer and the at least one ground interposer.
